(19) United States
(12) Patent Application Publication
(10) Pub. No.: US 2003/0118865 A1
(43) Pub. Date: Jun. 26, 2003

(54) High work function transparent conducting oxides as anodes for organic light-emitting diodes

(76) Inventors: Tobin J. Marks, Evanston, IL (US); He Yan, Evanston, IL (US); Jun Ni, Evanston, IL (US); Ji Cul, Waltham, MA (US); Anchuan Wang, Fremont, CA (US); Nikki L. Edleman, Pawling, NY (US)

Correspondence Address: REINHART BOERNER VAN DEUREN S.C., ATTN: LINDA GABRIEL, DOCKET COORDINATOR, 1000 NORTH WATER STREET, SUITE 2100, MILWAUKEE, WI, 53202, US

(21) Appl. No.: 10/228,521

(22) Filed: Aug. 27, 2002

Related U.S. Application Data
(60) Provisional application No. 60/315,159, filed on Aug. 27, 2001.

(51) Int. Cl. H05B 33/12; H01B 1/08

(52) U.S. Cl. 428/690; 428/917; 313/504; 313/503; 252/518.1; 427/66

(57) ABSTRACT

Transparent conducting oxide compositions having enhanced work function, for use with anode structures and light-emitting diode devices.

This application claims priority benefit of provisional application serial No. 60/315,159 filed Aug. 27, 2001, the entirety of which is incorporated herein by reference.

The United States government has certain rights to this invention pursuant to Grant Nos. CAMP MURI (N00014-95-1-1319) and DMR-0076097, to Northwestern University from the Office of Naval Research and National Science Foundation, respectively.

### BACKGROUND OF THE INVENTION

Impressive scientific and technological progress has recently been achieved in the area of organic light-emitting diodes (OLEDs), driven by potential applications in a large variety of display technologies. An equal fundamental research motivation has been the desire to better understand and control charge injection into, charge migration through, and radiative recombination in, molecular and macromolecular solids. Over the past few years, increasing activity has focused on improving charge injection efficiency at both OLED cathode/organic and anode/organic interfaces. (See, e.g., J. E. Malinsky, G. E. Jabbour, S. E. Shaheen, J. D. Anderson, A. G. Richter, N. R. Armstrong, B. Kipplelen, P. Dutta, N. Peyghambarian, T. J. Marks, Adv. Mater. 1999, 11, 227). Low work function metals (e.g., Ca, Mg) and combinations with other atmospherically stable metals (e.g., Ag, Al) have been implemented as cathodes, to afford improved luminous quantum efficiencies and lower operating voltages. (C. Zhang, D. Braun, A. J. Heeger, J. Appl. Phys. 1993, 73, 5177; J. Kido, K. Hongawa, K. Okuyama, K. Nagai, Appl. Phys. Lett. 1993, 63, 2627.) In contrast, relatively few materials have been explored as alternatives to Sn-doped In₂O₃ (ITO) as OLED anodes. As an n-doped, degenerate wide band gap semiconductor, ITO is used in numerous opto-electronics applications (e.g., photovoltaic cells, flat panel liquid crystal displays, “smart” windows, etc.) because of good transmittance in the visible and near-IR, low electrical resistivity, and easy processibility. (H. L. Hartnagel, A. L. Dawar, A. K. Jain, C. Jagadish, Semiconducting Transparent Thin Films, Institute of Physics, Bristol. 1995; Special Issue on Transparent Conducting Oxides, (Eds: D. S. Ginley, C. Bright), MRS Bulletin. August 2000, Vol. 25.)

However, the chemical and electronic properties of ITO are far from optimum for current and future generation OLEDs. Drawbacks include (1) deleterious diffusion of oxygen and In into proximate organic charge transporting/emissive layers (A. R. Schlatmann, D. W. Floet, A. Hillberer, F. Garten, P. J. M. Smulders, T. M. Klapwijk, G. Hadziioannou, Appl. Phys. Lett. 1996, 69, 1764; J. C. Scott, J. H. Kaufman, P. J. Brock, R. Dipietro, J. Salem, J. A. Goitia, J. Appl. Phys. 1996, 79, 2745), (2) imperfect (injection barrier-creating) work function alignment with respect to typical hole transport layer (HTL) HOMO levels (L. Chkoda, C. Heske, M. Sokolowski, E. Umbach, F. Steuber, J. Staudigel, M. Stossel, J. Simmerer, Synthetic Metals 2000, 111, 315; Y. Park, V. Choong, Y. Gao, B. R. Hsieh, C. W. Tang, Appl. Phys. Lett. 1996, 68, 2699; D. J. Milliron, I. G. Hill, C. Shen, A. Kahn, J. Schwartz, J. Appl. Phys. 2000, 87, 572), and (3) poor transparency in the blue region. (J. M. Philips, J. Kwo, G. A. Thomas, S. A. Carter, R. J. Cava, S. Y. Hou, J. J. Krajewski, J. H. Marshall, W. F. Peck, D. H. Rapkine, R. B. V. Dover, Appl. Phys. Lett. 1994, 65, 115.) Several alternative materials have been recently examined as anodes, including TiN, doped Si, Al-doped Zn, and F-doped SnO₂. However, all such materials suffer from some combination of poor optical transparency and/or significantly lower work functions than ITO, resulting in poor Fermi level energetic alignment with HTL HOMOs. Efforts continue in the art for an effective alternative to ITO and use thereof in OLED anode and device structures.

### SUMMARY OF THE INVENTION

In light of the foregoing, it is an object of the present invention to provide a variety of anode components or structures, related electroluminescent articles/devices and/or method(s) for their use, production and/or assembly, thereby overcoming various deficiencies and shortcomings of the prior art, including those outlined above. It will be understood by those skilled in the art that one or more aspects of this invention can meet certain objectives, while one or more other aspects can meet certain other objectives. Each objective may not apply equally, in all its respects, to every aspect of this invention. As such, the following objects can be viewed in the alternative with respect to any one aspect of this invention.

Accordingly, it is an object of the present invention to provide various alternatives to ITO materials for use in conjunction with electrode components, luminescent media and/or various electroluminescent devices, in particular transparent conducting oxides (TCOs) providing broader optical transparency windows, comparable or greater electrical conductivities and improved, higher work functions as compared to ITO and related semi-conductor materials or components of the prior art.

Other objects, features, benefits and advantages of the present invention will be apparent from this summary and its descriptions of various preferred embodiments, and will be readily apparent to those skilled in the art having knowledge of various electroluminescent devices and assembly/production techniques, together with the design and fabrication of related anode structures. Such objects, features, benefits and advantages will be apparent from the above as taken in conjunction with the accompanying examples, data, figures and all reasonable inferences to be drawn therefrom.

In part, the present invention is preferably embodied but not limited by the implementation of four new highly transparent, high work function thin film TCO materials as OLED anodes and related device structures: Ga—In—Sn—O (GITO), Zn—In—Sn—O (ZITO), Ga—In—O (GIO), and Zn—In—O (ZIO). Work function can be and is typically defined as the minimum energy needed to remove an electron from the Fermi level of a metal or metal composition, as expressed in electron volts (eV). Besides exhibiting high electrical conductivities (1000-3300 S/cm) and broad, outstanding optical transparencies (>90%), the present TCO films possess unusually high work functions (5.2-6.1 eV vs.˜4.7 eV for ITO). In particular, ZITO, having a work function of 6.1 eV, is the highest work function transparent anode material yet available for OLED fabrication. Conventional structure OLEDs fabricated with these anodes exhibit performance characteristics which differ in interesting, informative, and potentially useful ways from those of conventional ITO-based devices.

Accordingly, the present invention can be more broadly directed to an electroluminescent article or device including an anode fabricated from a TCO material of the type described herein. Such devices or articles together with various luminescent media or structural components can be designed and fabricated as described more fully in U.S. Pat. No. 5,834,100 and the patents cited therein, each of which are incorporated herein by reference in their entirety.

As such, the present invention can also be contemplated in a broader context so as to include an organic light-emitting diode device. Such a device comprises (1) an anode component comprising a metal conducting oxide material having a work function greater than 4.7 eV, (2) a cathode component, and (3) at least one organic conductive layer and/or component between the electrodes. A range of conducting oxide materials can be used with such a diode device, such materials as are currently known and available or as could be prepared using known synthetic techniques en route to the physical, functional and/or performance parameters described herein. Such considerations provide for use of a variety of Ga—In—O and Zn—In—O compositions over a range of stoichiometries. Preferred compositions include an Sn dopant. Sn-doped Zn—In—O compositions have been found especially useful, as described more fully herein. Without restriction to any one stoichiometric relationship, Zn_{0.45}In_{0.88}Sn_{0.66}O₃ is one such highly preferred composition given its work function alignment with the ionization potential of various organic compositions used in the fabrication of diode structures and devices.

As illustrated below, in several examples, such devices can be fabricated to include hole injection, hole transport, electron transport, electron injection and/or emissive layers, components and/or compositions. Such layers, components and/or compositions would be understood and known to those skilled in the art made aware of this invention, as would techniques relating to their preparation and inclusion in OLED device structures. However, as described more fully below, the present invention is demonstrated as especially useful in conjunction with blue light-emitting polymers and fabrication of the corresponding polymer light-emitting diodes. Without limitation, one such blue emitting polymer is poly(9,9-dioctylfluorene), the performance of which in a diode structure is significantly enhanced using one of several anode component materials of this invention.

As a corollary thereto, the present invention also includes a method of using a TCO material of the type described herein to improve, enhance or otherwise modify various anode properties and/or operating characteristics of OLED devices fabricated therewith, such properties and/or characteristics as discussed more fully below. More particularly, TCO materials, such as ZIO, GIO, GITO, and ZITO, exhibit high electrical conductivity, outstanding optical transparency, and work functions considerably greater than that of commercial ITO substrates. Optoelectric devices fabricated with such materials as anodes perform comparably or superior to ITO-based devices.

Accordingly, the present invention can also include an optoelectric anode component including a doped indium oxide composition having a work function greater than the reported value for ITO materials of the prior art. Preferably, such compositions have a work function greater than about 5.0 eV, such as can be obtained using either a Ga or Zn dopant, and providing the corresponding Ga—In—O and Zn—In—O compositions. Enchancement of various physical and/or functional characteristics and resulting performance properties can be realized with an anode component further including an Sn dopant, preferably providing a stoichiometric range of Ga—In—Sn—O and Zn—In—Sn—O compositions. Such an anode component is described herein and in the context of an OLED device, but use thereof can be extended as would be understood by those skilled in the art to other optoelectric devices. Alternatively, indium oxide can be doped with various other metal dopants such as but not limited to Sb, Pb, Ge, Al and Cd—the choice of which, amount and stoichiometry depending upon resulting work function. The corresponding doped compositions can be incorporated into an anode component as described more fully below.

In part, the present invention also includes one or more methods of using a TCO material of this invention and/or the doping thereof to reduce the energy difference between an anode comprising such a material and the highest occupied molecular orbital (HOMO) level of an associated OLED component. Such a difference is, at least in part, due to an improved work function and/or Fermi level position of the resulting anode relative to the energy level of a particular hole injection and/or emissive component, resulting in various performance properties of the type described herein. Such methods are effected by choice of an appropriate TCO material, anode fabrication and incorporation thereof into an OLED device.

As such, the present invention is also directed to a method of using energy level alignment to enhance the performance properties of an organic light-emitting diode device. Such a method includes (1) providing an anode component fabricated using a conductive oxide material, the material having a given work function; and (2) contacting the anode with a conductive layer component and/or composition having an ionization potential, the potential energy level aligned with the anode oxide work function level, such alignment defined by less than a 1.2 eV difference between the ionization potential and work function. For a particular conductive layer (e.g., hole injection, hole transfer, emissive, electron transfer and/or electron injection zones or components) an anode component and composition thereof can be designed to align corresponding energy levels. Alignment reduces the hole injection energy barrier of such a device and can be achieved through use of the present conductive oxide materials.

As a preferred embodiment, the present invention can also be considered in the context of conjugated polymer electroluminescence. Among the three primary colors, green and red polymer light-emitting diodes (PLEDs) have heretofor provided high brightness and quantum efficiency, while blue PLEDs have not previously demonstrated satisfactory performance for the purpose of display applications. Due to the high ionization potentials of most blue-emitting polymers, hole injection at the anode/polymer contact in a blue PLED is usually inefficient. For example, one of the most promising blue emitting polymers, poly(9,9-dioctylfluorene) (PFO), has a highest occupied molecular orbital (HOMO) level, or ionization potential, of 5.9 eV. Using a prior art indium-tin-oxide (ITO) (4.7 eV) as the anode, imposes a hole injection barrier of 1.2 eV.

Reducing the hole injection barrier is an integral step in the design of blue PLED devices, and one now available through the present invention. As mentioned earlier, the work function of a preferred zinc-indium-tin-oxide (ZITO) film is determined by ultra-violet photoelectron spectroscopy (UPS) to be 6.1 eV, which is significantly higher than that of ITO and aligns with the HOMO level (5.9 eV) of PFO. In a PLED device having ZITO as anode and PFO as emissive-layer (EL), the hole injection barrier is essentially overcome. As shown in the following examples, substituting ZITO for ITO as an anode material, in a PFO-based blue PLED device, provides a dramatic increase in device performance, as evidenced by a lower turn-on voltage, higher luminance, and higher quantum efficiency. Even so, as described herein, various other conductive layers, components and/or compositions can be utilized comparably with various other transparent conducting oxide materials of this invention.

### BRIEF DESCRIPTION OF THE DRAWINGS

FIG. 1. Fermi level, HOMO/LUMO energy level alignment of the OLED components fabricated with various transparent conducting anode materials.

FIGS. 2A-2B. 2A) Structure of a three layer OLED, 2B) Structures of OLED molecular components. Upon spin-coating, precursor I hydrolyzes and crosslinks to form hole injection/adhesion layer II.

FIGS. 3A-3C. A. Current density, B. Luminescence, and C. External quantum efficiency as a function of bias for TCO/TAA/TPD/Alq/Al OLED devices fabricated with the indicated transparent conducting oxide anodes and with commercial ITO.

FIG. 4. A schematic illustration showing ITO and ZITO diode device structures and comparing anode work functions with the ionization potential of a blue light-emitting polymer, PFO.

FIGS. 5A-5C. Comparing the diodes illustrated in FIG. 4, ZITO or ITO/PFO/Ca/Al (ITO ● and ZITO ▴): 5A) Light output, 5B) external quantum efficiency and 5C) current voltage characteristics as a function of operating voltage.

### EXAMPLES OF THE INVENTION

The following non-limiting examples and data illustrate various aspects and features relating to the conducting oxide materials, anodes and/or devices of the present invention, including improved anode conductivities and work functions, as are available through use of the TCO materials described herein. Such aspects and features are described in more detail, hereafter. In comparison with the prior art, the present materials, anodes and articles/devices provide results and data which are surprising, unexpected and contrary to the prior art. While the utility of this invention is illustrated through the use of several TCO materials and related anode structures fabricated therewith, it will be understood by those skilled in the art that comparable results are obtainable with various other TCO materials, components and anode structures, as are commensurate with the scope of this invention.

Likewise, without limitation, the present invention can be described and illustrated by four representative TCO materials, each of which can be prepared, isolated and/or characterized as described in the prior art:

GITO: A. Wang, N. L. Edleman, J. R. Babcock, T. J. Marks, M. A. Lane, P. W. Brazin, C. R. Kannewurf, Mat. Res. Soc. Symp. Proc. 2000, 607, 345; A. J. Freeman, K. R. Poeppelmeier, T. D. Mason, R. P. H. Chang, T. J. Marks, MRS Bull. 2000, 25, 45.

ZITO: A. Wang, N. L. Edleman, J. R. Babcock, T. J. Marks, M. A. Lane, P. W. Brazis, C. R. Kannewurf, Mater. Res. Soc. Symp. Proc. 2000, 607, 345. A. J. Freeman, K. R. Poeppelmeier, T. D. Mason, R. P. H. Chang, T. J. Marks, MRS Bull. 2000, 25, 45;

GIO: A. Wang, S. C. Cheng, J. A. Belot, R. J. Mcneely, J. Cheng, B. Marcordes, T. J. Marks, J. Y. Dai, R. P. H. Chang, J. L. Schindler, M. P. Chudzik, C. R. Kannewurf, Mat. Res. Soc. Symp. Proc. 1998, 495, 3; and

ZIO: A. Wang, J. Dai, J. C. Cheng, M. P. Chudzik, T. J. Marks, R. P. H. Chang, C. R. Kannewurf, Appl. Phys. Lett. 1998, 73, 327. A. Wang, S. C. Cheng, J. A. Belot, R. J. Mcneely, J. Cheng, B. Marcordes, T. J. Marks, J. Y. Dai, R. P. H. Chang, J. L. Schindler, M. P. Chudzik, C. R. Kannewurf, Mat. Res. Soc. Symp. Proc. 1998, 495, 3. Y. Yan, S. J. Pennycook, J. Dai, R. P. H. Chang, A. Wang, T. J. Marks, Appl. Phys. Lett. 1998, 73, 2585.

### Example 1

Growth conditions (MOCVD) on float glass substrates and characterization of ZITO, ZIO, GITO, and GIO thin films by X-ray diffraction, SEM, TEM, and AFM, as well as by other compositional, electrical, and microstructural techniques have been described previously. Microstructurally, all have homogeneously doped cubic In₂O₃ bixbyite crystal structures, and surface rms roughnesses comparable to commercial ITO. Effective work functions were determined by UV spectroscopy using the 21.8 eV He (I) source (Omicron H1513) of a Kratos Axis-Ultra 165 photoelectron spectrometer. (R. Schlaf, B. A. Parkinson, P. A. Lee, K. W. Nebesny, N. R. Armstrong, Appl. Phys. Lett. 1998, 73, 1026.) Work functions were obtained by lightly sputtering the TCO surface with an Ar⁺ beam (1 keV), to remove adventitious impurities (as revealed by XPS) and then recording the difference in energy between the high kinetic energy onset and the low kinetic energy cutoff for photoionization. Samples were biased at −5 V to enhance the slope of the low kinetic energy cutoff region. Estimates of the high kinetic energy onset for photoionization were obtained by extrapolation of the high kinetic energy portion of the photoemission spectrum to the zero count baseline. The work function determined here for commercial ITO, 4.7 eV, is in the range typically reported. (R. Schlaf, B. A. Parkinson, P. A. Lee, K. W. Nebesny, N. R. Armstrong, Appl. Phys. Lett. 1998, 73, 1026.)

### Example 2

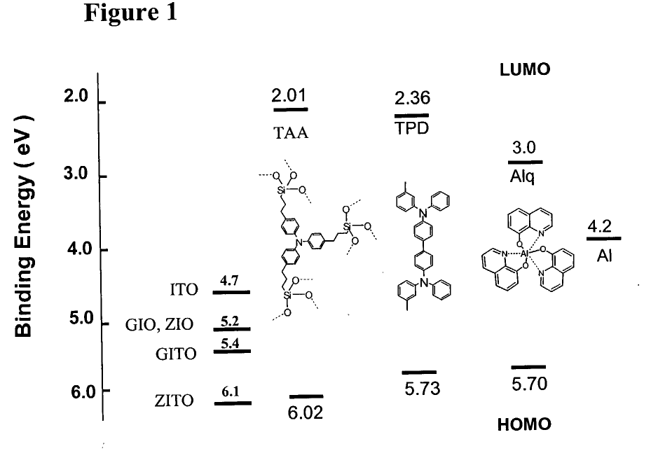

Relevant properties of several TCO anodes of this invention are summarized in Table 1, below. Note that all have lower optical absorption coefficients than commercial ITO (Donelley Corp., 20 Ω/□). The visible transparency windows of these films are also significantly broader than that of ITO. (A. Wang, N. L. Edleman, J. R. Babcock, T. J. Marks, M. A. Lane, P. W. Brazis, C. R. Kannewurf, Mater. Res. Soc. Symp. Proc. 2000, 607, 345.) Although ZIO and GIO have somewhat lower n-type conductivities (700-1000 S/cm) than commercial ITO (˜3000 S/cm), the Sn-doped versions (GITO, ZITO) exhibit comparable values (2000-3300 S/cm). As currently understood, GITO and ZITO are the most transparent and among the most conductive TCO materials available for OLED fabrication. In terms of robustness, all of the present films are more chemically inert than commercial ITO; e.g., to remove a 120 nm thick ITO film using 20% aqueous HCl at 25° C. requires ˜5 min, while comparable degradation of GITO or GIO films requires ˜4×longer. FIG. 1 summarizes TCO work function data and Fermi level positions relative to the energy levels of the components to be used in OLED fabrication (vide infra): the HOMOs of a crosslinked triarylamine (TAA) adhesion/injection layer and TPD hole transport layer (HTL), as well as the LUMO of the aluminum tris-quinoxalate (Alq) electron transport layer (ETL). (H. Ishii, K. Sugiyama, E. Ito, K. Seki, Adv. Mater. 1999, 11, 605.) These data are a measure of the intrinsic hole injection barrier, i.e., the energy offset between the organic HOMO level and the TCO Fermi level, in absence of other interfacial structural or electronic barriers. (H. Ishii, K. Sugiyama, E. Ito, K. Seki, Adv. Mater. 1999, 11, 605.) Note that all the present non-ITO TCO materials have work functions significantly greater than that of commercial ITO—indeed, the work function of the GITO films rivals that of Au (5.4 eV) while the value of ZITO (6.1 eV) is greater than that of Pt (5.7 eV). S. M. Sze, Physics of Semiconductor Devices, Wiley, New York 1981.

TABLE 1
Physical Properties of TCO Anode Films on Glass Substrates.

| | | Sheet | | Absorption | Work |
|---|---|---|---|---|---|
| Anode Material | Thickness | Resistance | Conductivity | Coefficient (cm⁻¹⁾ | Function |
| [reference] | (nm) | (Ω/□) | (S/cm) | (at 550 nm) | (eV) |
| Ga_{0.12} In_{1.88}O₃ | 1020 | 14 | 700 | 1100 | 5.2 |
| Ga_{0.08}In_{1.28}Sn_{0.64}O₃ | 170 | 18 | 3280 | 2000 | 5.4 |
| Zn_{0.5}In_{1.5}O₃ | 250 | 39 | 1030 | 800 | 5.2 |
| Zn_{0.45}In_{0.88}Sn_{0.66}O₃ | 360 | 12 | 2290 | 2700 | 6.1 |
| ITO^{a} | 180 | 20 | 3500 | 8075 | 4.7 |

^{a}ITO received from Donelley Corp., 20 Ω/□; other anode materials available and/or prepared as described above.

### Example 3

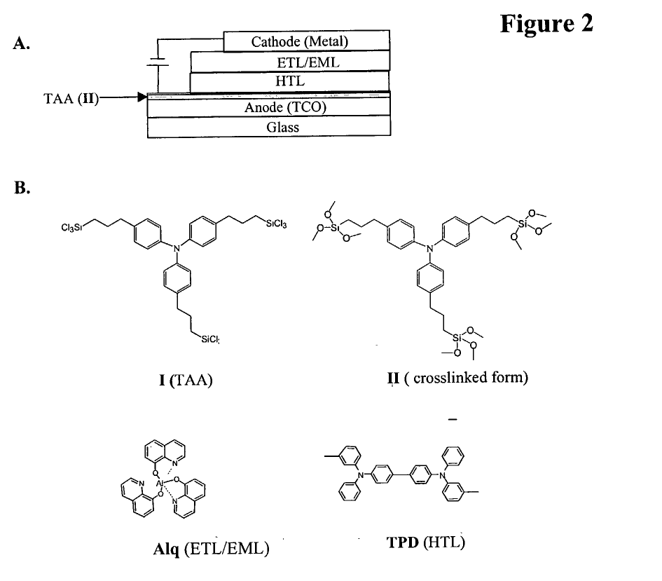

For OLED fabrication, the as-grown TCO and commercial ITO films were subjected to identical sequential cleaning with HPLC grade acetone, isopropanol, and methanol, then with an oxygen plasma to eliminate organic residues. All of the freshly cleaned metal oxide surfaces are highly hydrophilic as evidenced by advancing aqueous contact angles of ˜0⁰. A thin, crosslinked TAA layer derived from N(4-C₆H₄CH₂CH₂CH₂SiCl₃)₃ (I, FIG. 2) was then spin-coated onto each of the anode surfaces from a 1 mM toluene solution and cured at 120° C. for 1.0 hour. This layer has been shown in previous work to enhance TCO/HTL interfacial cohesion and charge injection efficiency. The TAA films are robust, adherent, contiguous, and electroactive, with ˜1.5 nm RMS roughness on all TCO substrates, and having a thickness of 15 nm (by X-ray reflectivity.) (W. Li, J. E. Malinsky, H. Chou, W. Ma, L. Geng, T. J. Marks, G. E. Jabbour, S. E. Shaheen, B. Kippelen, N. Pegyhambarian, A. J. R. P. Dutta, J. Anderson, P. Lee, N. Armstrong, Polymer Preprints. 1998, 39, 1083.) Subsequent vacuum deposition (5×10⁻⁶ Torr) of 50 nm of N,N′-diphenyl-N,N′-bis(3-methylphenyl)-1,1′-biphenyl-4-4′ diamine (TPD) and 60 nm of gradient-sublimed aluminum tris-quinoxalate (Alq), followed by 100 nm of Al completed device fabrication (FIG. 2A.). The OLEDs were characterized inside a sealed aluminum sample container under a dry nitrogen atmosphere. A Keithley 2400 source meter supplied d.c. voltage to the devices and simultaneously recorded the current flow. Simultaneously, an IL 1700 research radiometer with calibrated Si photodetector was used to collect the photon emission. These instruments were controlled by a PC via LabView software.

### Example 4

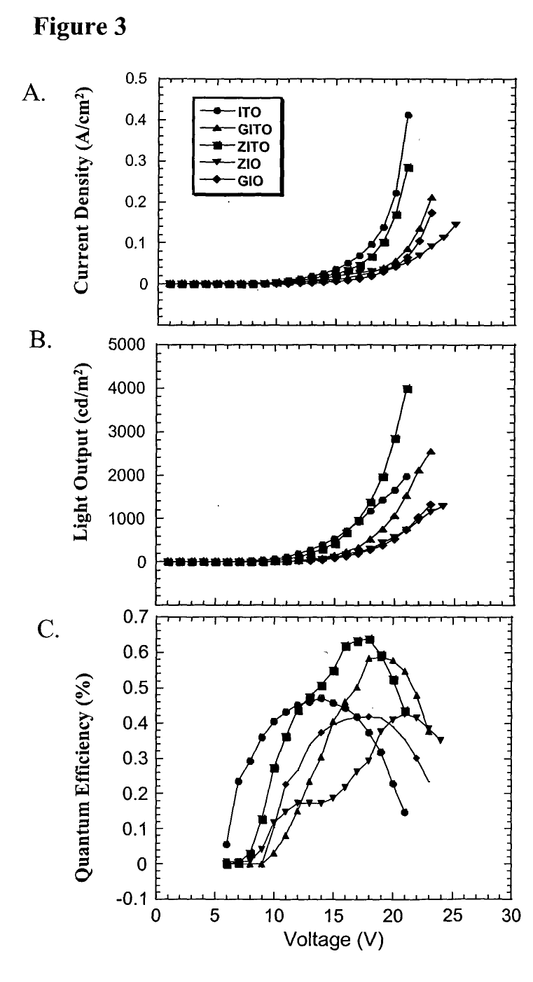

The operating characteristics of OLED devices fabricated, as described in the preceding example, with the present TCO and ITO anodes are compared and illustrated in FIG. 3. All show typical diode behavior with no current drawn in reverse bias, and in all cases, light turn-on occurs simultaneously with current turn-on. Within the 1.0 cd/m² photon detector resolution, the threshold voltage for light output varies significantly among the devices: 6.0 V for ITO, and 7.5, 9.0, 10.0, and 10.0 V for ZITO, ZIO, GITO, and GIO, respectively (Table 2, below). Regarding maximum light output, a brightness of ˜1400 cd/m² is obtained for the GIO- and ZIO-based devices. While the GITO-based device has a maximum light output comparable to that of the ITO-based device (˜2500 cd/m² at 22 V), the ZITO-based device exhibits a maximum brightness ˜80% greater than the ITO-based device. At 21 V, a maximum brightness of 4000 cd/m² is observed for ZITO-based device at a current density corresponding to 0.7× the value for the ITO-based device. Remarkably, at high driving voltages, which should be a measure of durability under extended use/stress, the forward quantum efficiencies of the ZITO- and GITO-based OLEDs (˜0.6%) far exceed that of the present ITO-based OLED (˜0.3%).

TABLE 2
Operating characteristics of OLED devices fabricated with various TCO
anodes.

| | | Current | | | Maximum |
|---|---|---|---|---|---|
| | ^{a}Turn-on | Density at | Light Output at | Maximum | External |
| | Voltage | 100 cd/m² | 15 V | Forward Light | Quantum |
| Anode Material | (V) | (mA/cm²) | (cd/m²) | Output (cd/m²) | Efficiency (%) |
| Ga_{0.12} In_{1.88}O₃ | 10 | 9.5 | 80 | 1320 | 0.4 |
| Ga_{0.08}In_{1.28}Sn_{0.64}O₃ | 10 | 9.7 | 150 | 2560 | 0.6 |
| Zn_{0.5}In_{1.5}O₃ | 9 | 19 | 110 | 1290 | 0.4 |
| Zn_{0.45}In_{0.88}Sn_{0.66}O₃ | 8 | 8.3 | 430 | 4000 | 0.6 |
| ITO | 6 | 8.5 | 540 | 1960 | 0.5 |

^{a.}Defined as the voltage at which 1 cd/m² light output is detected.

### Example 5

Regarding OLED efficiency as a function of anode composition, it can be seen that Sn doping of the Ga—In—O and Zn—In—O systems substantially increases the conductivity, increases the work function, and yields superior OLED anodes. Note that the quantum efficiency and maximum light output of the GITO- and ZITO-based devices significantly exceeds that of the corresponding GIO- and ZIO-based devices, respectively. Apart from compositional differences, differences in work function among the new TCO materials should also be reflected in the respective OLED device performance, and indeed, within the GIO, ZIO, GITO, ZITO series, the apparent hole injection facility at moderate biases approximately tracks work function (Table 2, FIG. 3B), ZITO>GITO>ZIO˜GIO. In the case of ZITO, hole injection from the ZITO anode into the proximate TAA layer should be energetically quite favorable due to the high ZITO work function, which lies significantly below the TAA HOMO level (FIG. 1). All other things being equal, the intrinsic hole injection barrier should be smaller for the ZITO/TAA interface than for the ITO/TAA interface, hence more efficient charge injection would be expected in ZITO-based devices. However, other factors appear operative. (FIG. 3). Although ITO has a 4.7 eV work function and a substantial estimated intrinsic hole injection barrier of ˜1.3 eV with respect to the TAA HOMO, the ITO-based device nevertheless exhibits ˜1.5 V lower turn-on voltage than the ZITO-based device and higher quantum efficiencies at low voltages. The lower conductivities of other TCOs (Table 1) cannot be invoked to explain these results, considering that the range of respective sheet resistances (12 Ω/□-39 Ω/□) spans that of ITO, and should not lead to a large voltage drop across the TCO surface. Likewise, improved charge injection balance (J. E. Malinsky, G. E. Jabbour, S. E. Shaheen, J. D. Anderson, A. G. Richter, N. R. Armstrong, B. Kipplelen, P. Dutta, N. Peyghambarian, T. J. Marks, Adv. Mater. 1999, 11, 227) via attenuation of hole injection cannot alone explain these results, since all other factors being equal, ZITO should inject holes more efficiently than ITO due to the lower intrinsic barrier, meaning all other factors being equal, a greater number of photonically unproductive holes should reach the cathode, resulting in a lower quantum efficiency. Note here, however, that the ZITO device operates at higher quantum efficiencies at high voltage ranges (FIG. 3C). Control experiments argue that anode growth technique is not a major factor since devices fabricated with MOCVD-derived ITO anodes exhibit quantum efficiencies comparable to those of devices fabricated with commercial ITO with slightly diminished turn-on voltages.

### Example 6

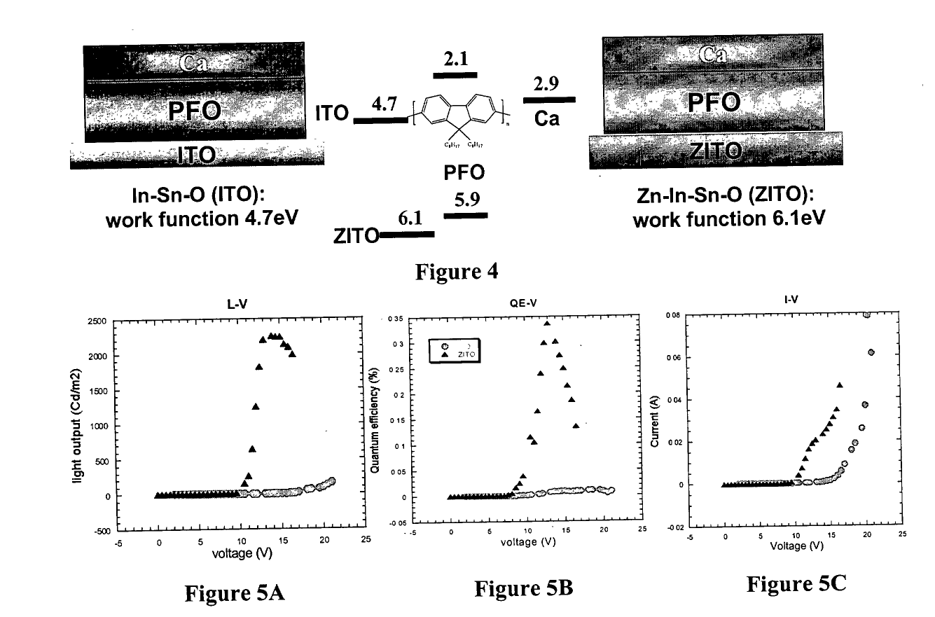

The chemical structure of PFO is shown in FIG. 4. The polymer was synthesized via a Suzuki coupling reaction and was carefully purified to remove ionic impurities and catalyst residues. The number and weight average molecular weights (Mₙ and M_{w}) of PFO were determined to be 54,700 and 106,975 (polydispersity=1.95), respectively, by gel permeation chromatography (GPC) using tetrahydrofuran as the solvent and polystyrene as the standard. ITO or ZITO coated glass was used as the substrate for PLEDs device fabrication. The substrates were first washed with methanol, iso-propanol, and acetone in an ultrasonic bath, dried in a vacuum oven, and then cleaned by oxygen plasma etching. PFO was spincast on the substrates from a xylene solution to give an emissive layer of a thickness about 80 nm. The resulting films were dried in a vacuum oven overnight. Inside an inert atmosphere glove box, calcium was thermally evaporated onto the PFO films over a base pressure <10⁻⁶ Torr using a shadow mask to define 10 mm² electrode area, followed by aluminum deposition as a protection layer. The PLED devices were characterized inside a sealed aluminum sample container using instrumentation described elsewhere.

### Example 7

The PLED devices fabricated in the preceding example were compared. The device characteristics of the ITO and ZITO PLED devices are shown in FIGS. 5A-C, respectively, for comparaison of luminance-voltage(L-V), external quantum efficiency-voltage, and current-voltage(I-V). It can be clearly seen that the ZITO-based PLED device shows dramatic increase in charge carrier injection, brightness, and quantum efficiency compared to the ITO-based device; it turns on at about 8 V and reaches maximum luminance of about 2200 cd/m² at about 13 V and with an external quantum efficiency of 0.337%, while the ITO based device turns on at 12 V and reaches maximum luminance of about 200 cd/m² at 21 V and with an external quantum efficiency of 0.01%.

### Example 8

Other PLED devices of this invention can be fabricated to include one or more additional organic layers and/or components of the prior art, such as but not limited to a hole injection layer and a hole transport layer. Illustrating the former is a triarylaminesiloxane (TAA) of the sort described above which can be fabricated using molecular self-assembly techniques. Various thiophene polymers can be spincast. With regard to a hole transport layer, known compositions of the prior art—irrespective of fabrication technique—can be utilized with good effect. In one such embodiment, TPD can be vapor deposited or silane funtionalized and applied via molecular self-assembly techniques. Such layer, roughened—as would be understood by those skilled in the art, can be used to further improve the performance enhancement demonstrated herein.

As provided above, anode work function is an important contributing factor in determining OLED hole injection barrier and device performance. However, other factors can be considered in conjunction therewith. For instance, for microstructurally very similar materials, anode work function is one variable governing OLED charge injection and exciton recombination efficiency, and can be considered with other variables such as electrode surface morphology, composition, and surface electronic states. Even so, the intrinsically high work function TCO materials and anodes of this invention can be used as described, above, for hole-limited OLEDs, or oxidation-resistant, atmospherically stable OLEDs for which energetic alignment with low-lying HOMO levels of organic layers and high work functions of air-stable cathodes are required. Furthermore, preliminary studies of device operational stabilities by biasing the devices under constant dc voltage reveal that OLEDs fabricated with the present non-ITO TCOs exhibit significantly higher stabilities (≧2×longer luminescence decay half-lives) than commercial ITO-based devices.

### Example 9

Indium oxide is doped, alternatively, with Sb, Pb, Ge, Al or Cd to provide the corresponding composition, over a range of stoichiometries. Such compositions can be, as further required by work function and hole injection barrier considerations, in turn doped with varying amounts of Sn. The preparation of such compositions can be achieved using techniques of the prior art, references to which are provided above and incorporated herein, or through straight-forward modifications thereof as would be understood by those skilled in the art and made aware of this invention.

While the principles of this invention have been described in connection with specific embodiments, it should be understood clearly that these descriptions are added only by way of example and are not intended to limit, in any way, the scope of this invention. For instance, while several representative TCO materials with the stoichiometries shown have been used to illustrate certain aspects of this invention, various other materials and/or stoichiometries limited only by availability and the conductivities, work functions and related performance properties afforded therewith are contemplated within the broader scope of this invention. Other advantages and features will become apparent from the claims presented hereafter, with the scope of those claims determined by the reasonable equivalents, as would be understood by those skilled in the art.

What is claimed:

1. An organic light-emitting device comprising an anode component comprising a metal conducting oxide material having a work function greater than 4.7 eV, a cathode component and at least one organic conductive layer therebetween.

2. The device of claim 1 wherein said anode component material is selected from the group consisting of Ga—In—O compositions, Zn—In—O compositions and said compositions doped with Sn.

3. The device of claim 2 wherein said component material is a Sn-doped Zn—In—O composition.

4. The device of claim 3 wherein said Zn—In—O composition is Zn_{0.45}In_{0.88}Sn_{0.66}O₃.

5. The device of claim 2 wherein one said conductive layer comprises a hole injection layer.

6. The device of claim 2 wherein one of said conductive layers comprises a hole transport layer.

7. The device of claim 2 wherein one said conductive layer comprises a primary color light-emitting polymeric composition.

8. The device of claim 7 wherein said polymeric composition is poly(9,9-dioctylfluorene) and said anode component material is a Sn-doped Zn—In—O composition.

9. The device of claim 8 further including a hole injection layer on said anode component, said injection layer comprising a triarylamine composition.

10. An optoelectric anode component comprising a doped indium oxide composition having a work function greater than about 5.0 eV.

11. The anode component of claim 10 wherein said dopant is selected from the group consisting of Ga and Zn.

12. The anode component of claim 11 wherein said composition is selected from the group consisting of Ga—In—O and Zn—In—O.

13. The anode component of claim 11 further including an Sn dopant, wherein said composition is selected from the group consisting of Ga—In—Sn—O and Zn—In—Sn—O.

14. A method of using energy level alignment to enhance the performance properties of an organic light-emitting diode device, said method comprising:
providing an anode component comprising a conductive oxide material, said material having a work function; and
contacting said anode with a conductive layer comprising an organic composition having an ionization potential, said ionization potential level and said work function level aligned, said alignment defined by a difference between said ionization potential and said work function less than 1.2 eV.

15. The method of claim 14 wherein said conducting oxide material is selected from the group consisting of Ga—In—O compositions, Zn—In—O compositions and said compositions doped with Sn.

16. The method of claim 15 wherein said composition is an Sn-doped Zn—In—O composition.

17. The method of claim 14 wherein said conductive layer comprises at least one of a hole injection component, a hole transport component and an emissive component.

18. The method of claim 17 wherein said emissive component comprises a blue light-emitting polymeric composition spincast on said anode component.

19. The method of claim 18 wherein said anode component is Zn_{0.45}In_{0.88}Sn_{0.66}O₃, having a work function of about 6.1 eV.

20. The method of claim 19 wherein said polymeric composition is poly(9,9-dioctylfluorene) having a work function of about 5.9 eV.
